(19) United States
(12) Patent Application Publication
(10) Pub. No.: US 2005/0275423 A1
(43) Pub. Date: Dec. 15, 2005

(54) System and method for checking a layout of circuit traces on a PCB

(75) Inventors: Hung-Yuan Tsai, Tu-cheng (TW); Jie Peng, Shenzhen (CN); Hao Wu, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 10/997,402

(22) Filed: Nov. 23, 2004

(30) Foreign Application Priority Data
Jun. 12, 2004 (CN) 200410027688.9

(51) Int. Cl. G01R 31/26

(52) U.S. Cl. 324/765

(57) ABSTRACT

A system for checking a layout of circuit traces on a printed circuit board (PCB) includes a computer (1) and a database (2). The database stores information generated and used by the system. The computer includes: a checking area creating module (101) for creating checking areas; a layout determining module (102) for determining whether a vertical projection of a trace to be checked intersects on any same potential area on a reference layer; a via information obtaining module (103) for determining whether any via exists in a checking area; a capacitor determining module (104) for determining whether any capacitor exists in a checking area, and determining whether the capacitors in the checking area have been listed in a user-selected capacitor list; and an area determining module (105) for determining whether same potential areas are identical according to information on the same potential areas. Related methods are also disclosed.

### BACKGROUND OF THE INVENTION

1. Field of the Invention

The present invention relates to a system and method for checking a layout of circuit traces on a printed circuit board (PCB).

2. Related Art of the Invention

Electronic components on a printed circuit board (PCB) must be properly positioned to reduce or eliminate electromagnetic interference (EMI). EMI is an electrical disturbance in an electronics-based system such as a computer system. It can be caused by natural phenomena such as lightning, or by high-frequency waves emitted from integrated traces and other electronic components. Standards have been established which stipulate the maximum EMI which various devices are allowed to generate. These standards are referred to as electromagnetic compatibility (EMC) standards. In the United States, the Federal Communications sets limits on the EMI output of electronic components. Other countries set their own limits on the EMI output of electronic components too. Therefore, when a design engineer designs the PCB, he/she must ensure that EMI emissions coming from the circuits positioned on the PCB are at or below the maximum levels allowed in relevant jurisdictions.

A crowded PCB generally has a number of splits distributed thereon, whereby the splits can potentially interfere with the intended flow of electrical current. If a current encounters a split, the current is liable to be diverted to other areas of the PCB that are full of electrical devices and cause EMI. To remedy this situation, capacitors can be employed to conduct the current and thereby divert it from flowing to other areas full of electrical components. A design engineer typically places a number of capacitors on the PCB, such that the capacitors enable the current to bypass the splits.

Once the layout is designed, it must be verified to insure that traces have been properly placed in order to reduce EMI. Traditional methods of verifying the layout rely heavily on sheer manpower, and cannot precisely check whether traces on the PCB have been correctly laid out. These methods are time consuming, and do not always prevent PCBs with inexact layouts being produced. Thus, there is a need for a system and method which can automatically check whether traces on a PCB have been correctly laid out.

### SUMMARY OF THE INVENTION

Accordingly, a primary objective of the present invention is to provide a system for automatically checking whether a layout of circuit traces on a printed circuit board (PCB) is correct as regards EMI considerations.

A second objective of the present invention is to provide a method for automatically checking whether a layout of circuit traces, each of which is routed on a same layer of a PCB, is correct as regards EMI considerations.

A third objective of the present invention is to provide a method for automatically checking whether a layout of circuit traces, each of which is routed on more than one layer of a PCB, is correct as regards EMI considerations.

To accomplish the above-mentioned primary objective, a system for checking a layout of circuit traces on a PCB (hereinafter “the system”) is provided herein. The system can automatically check whether traces on a PCB have been correctly laid out, and comprises a computer, a database, and a connection which connects the computer with the database. The database comprises two logically separated storages: a standard layout information storage and an actual layout information storage. The standard layout information storage stores preset standard layout information on the PCB. Such standard layout information includes standard layout information on the traces, and standard information on vias and capacitors. The actual layout information storage stores actual layout information on the PCB. Such actual layout information includes actual layout information on the traces, actual information on the vias and the capacitors, and information on areas at same potentials (hereinafter, “the same potential areas”).

The computer comprises: a checking area creating module for creating checking areas according to the standard layout information obtained from the standard layout information storage; a layout determining module for obtaining a reference layer of a signal layer on which a trace to be checked is routed, and determining whether a vertical projection of the trace intersects borders of any same potential areas on the reference layer; a via information obtaining module for obtaining reference layers of signal layers connected by a via, and determining whether any via exists in a checking area; a capacitor determining module for determining whether any capacitor exists in a checking area, and determining whether the capacitors in the checking area have been listed in a user-selected capacitor list; and an area determining module for obtaining information on the same potential areas from the actual layout information storage, and determining whether the same potential areas are identical according to the information on the same potential areas.

To accomplish the above-mentioned second objective, a method for checking a layout of circuit traces, each of which is routed on a layer of a PCB, is provided herein. The method comprises the steps of: (a1) selecting a trace which is routed on only one signal layer of the PCB to be checked; (b1) obtaining a reference layer of the signal layer on which the trace is routed, and obtaining information on each same potential area on the reference layer where a vertical projection of the trace stands; (c1) determining whether the vertical projection of the trace on the reference layer intersects a border of any same potential area identified in step (b1); (d1) obtaining standard layout information on the PCB from a standard layout information storage, and creating a checking area according to the standard layout information on the trace if the vertical projection of the trace intersects the border of any same potential area identified in step (b1), wherein this step and the following steps apply in respect of each same potential area; (e1) determining whether any capacitor exists in the checking area; (f1) determining whether the capacitor has been listed in a user-selected capacitor list if any capacitor exists in the checking area; and (g1) considering the trace as being correctly laid out with respect to the same potential area, if the capacitor has been listed in the user-selected capacitor list.

To accomplish the above-mentioned third objective, a method for checking a layout of circuit traces, each of which is routed on more than one layer of a PCB, is provided herein. The method comprises the steps of: (a2) selecting a trace to be checked, wherein the trace has been routed on more than one of signal layers of the PCB; (b2) obtaining actual information on a via of the trace; (c2) obtaining two reference layers of two signal layers on which the trace is routed; (d2) obtaining information on the same potential areas which connect to the via on the two reference layers; and (e2) determining whether electrical characteristics of the two same potential areas are identical.

If the electrical characteristics of the two same potential areas are identical, the method further includes the steps of: (a3) considering the two same potential areas as one potential area, and designating them a as “Via-area;” (b3) obtaining standard layout information on the PCB and creating a checking area according to the standard layout information; (c3) determining whether any via exists in the checking area; (d3) obtaining same potential areas connects to the via if any via exists; (e3) determining whether electrical characteristics of the same potential areas are identical to the electrical characteristics of the “Via-area;” and (f3) considering that the trace is correctly laid out if the electrical characteristics of the same potential areas are identical to the electrical characteristics of the “Via-area.”

If the electrical characteristics of the two same potential areas are not identical, the method further includes the steps of: (a4) designating the two same potential areas a “Via-area I” and a “Via-area II” respectively; (b4) obtaining standard layout information on the PCB and creating a checking area according to the standard layout information; (c4) determining whether any capacitor exists in the checking area; (d4) obtaining same potential areas which connects to pins of the capacitor, for each capacitor identified in step (c4), if any capacitor exists in the checking area; (e4) determining whether electrical characteristics of each same potential area are identical to the electrical characteristics of either “Via-area I” or “Via-area II,” whichever of “Via-area I” and “Via-area II” is located on the same reference layer; and (f4) considering that the trace is correctly laid out if, for each capacitor identified in step (c4), the electrical characteristics of each of the same potential areas are identical to the electrical characteristics of the applicable “Via-area I” or “Via-area II.”

These and other objects, advantages and novel features of the present invention will be drawn from the following detailed description with reference to the appended drawings, in which:

### BRIEF DESCRIPTION OF THE DRAWINGS

FIG. 1 is a schematic diagram of hardware infrastructure of a system for checking a layout of circuit traces on a PCB according to the preferred embodiment of the present invention;

FIG. 2 is a schematic, cross-sectional view of parts of layers of an exemplary PCB, showing certain components including traces of the PCB;

FIG. 3 is a schematic, planform view of part of the exemplary PCB, showing certain components including a trace of the PCB;

FIG. 4 is a schematic diagram of function modules of a programmable layout checking apparatus of a computer of the system of FIG. 1;

FIG. 5 is a flowchart of a preferred method for checking whether circuit traces, each of which is routed on a same signal layer of a PCB, have been correctly laid out, according to the present invention;

FIG. 6 is a flowchart of details of one step of FIG. 5, namely determining whether a vertical projection of a trace on a reference layer intersects a border of any same potential area on the reference layer; and

FIG. 7 is a flowchart of a preferred method for checking whether circuit traces, each of which is routed on more than one signal layer of a PCB, have been correctly laid out, according to the present invention.

### DETAILED DESCRIPTION OF THE PREFERRED EMBODIMENT

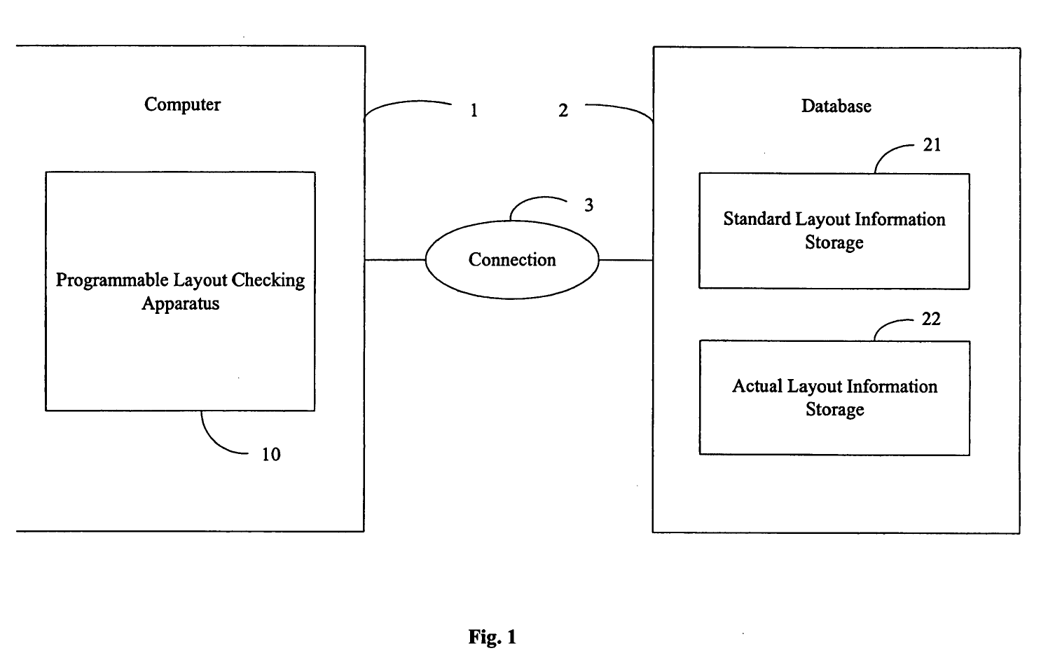

FIG. 1 is a schematic diagram of hardware infrastructure of a system of the present invention for checking a layout of circuit traces on a printed circuit board (PCB) (hereinafter, “the system”). The system comprises a computer 1, a database 2, and a connection 3 which connects the computer 1 with the database 2. The connection 3 is a database connectivity, such as an Open Database Connectivity (ODBC) or a Java Database Connectivity (JDBC). The database is used for storing information used and generated by the system, and comprises two logically separated storages: a standard layout information storage 21, and an actual layout information storage 22.

The standard layout information storage 21 stores preset standard layout information on the PCB. Such standard information includes standard layout information on traces, and standard information on capacitors and vias. The actual layout information storage 22 stores actual layout information on the PCB. Such actual information includes actual layout information on the traces, actual information on the capacitors and vias, and information on areas that are at same potentials (hereinafter, “same potential areas”). The information on the same potential areas includes names of the same potential areas. In the preferred embodiment of the present invention, the names of the same potential areas are determined by electrical characteristics of the same potential areas and reflect the electrical characteristics of the same potential areas. The computer 1 comprises a programmable layout checking apparatus 10, which can automatically check whether the traces on the PCB have been correctly laid out. Each trace may be routed on a same signal layer, or may be routed on more than one signal layer.

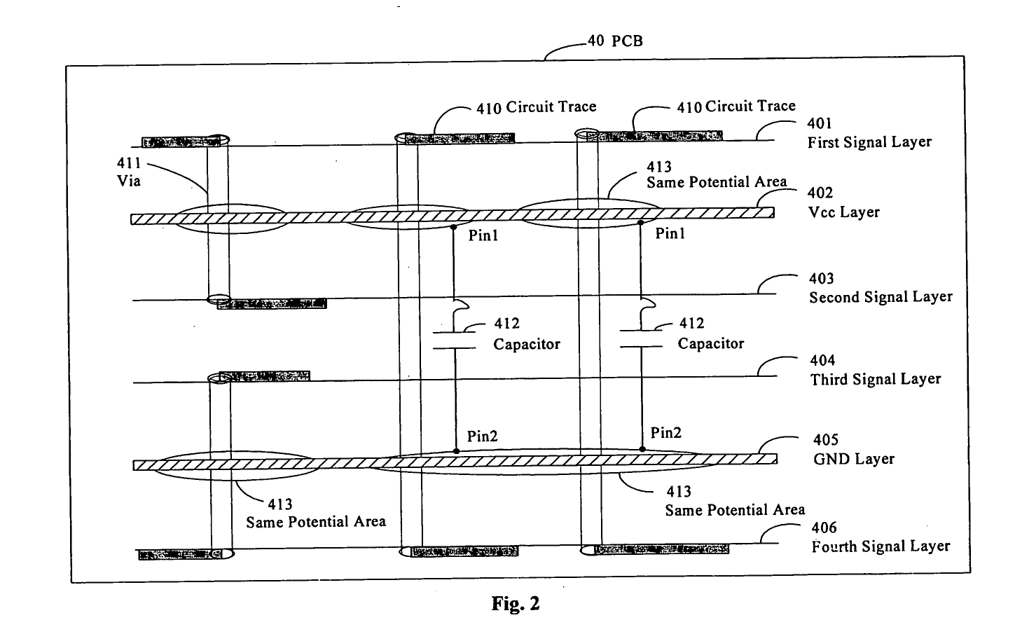

FIG. 2 is a schematic, cross-sectional view of parts of layers of an exemplary PCB 40, showing certain components including traces 410 of the PCB 40. For simplicity, the PCB 40 is assumed to be a 6-layer PCB. Nevertheless, the description should not be construed as limiting the invention to the PCB 40 having any particular number of layers. The layers of the PCB 40 are labeled 401-406 from top to bottom. The layers 401, 403, 404 and 406 are signal layers used to route circuit traces 410. The other two layers 402 and 405 are reference layers for the four signal layers 401, 403, 404 and 406, and are respectively called a Vcc layer 402 and a ground (GND) layer 405.

The traces 410 are routed on one or more of the signal layers 401, 403, 404 and 406, and segments of a same trace 410 routed on two or more different of the signal layers 401, 403, 404 and 406 are joined by one or more vias 411. According to the preferred embodiment of the present invention, in order to determine whether each of the traces 410 on the PCB 40 has been correctly laid out, and to reduce EMI arising from an incorrect placement of any trace 410, several parameters need to be checked. Such parameters include a layout of segments of the trace 410, and vias 411, capacitors 412 and same potential areas 413 that are related to the trace 410. All of these parameters describe change information of locations of the reference layer 402, 405 relative to the trace 410. According to the preferred embodiment, each capacitor 412 connects two same potential areas 413, and is used for returning currents to flow from one of the same potential areas 413 to the other of the potential areas 413 when needed, thereby reducing EMI. The same potential areas 413 are mainly distributed on the Vcc layer 402 and the GND layer 405, and are classified and named according to their electrical characteristics. In the preferred embodiment, if a same potential area 413 connects with a via 411, it is called a “Via-area.” If the “Via-area” is located on the Vcc layer 402, it is called a “Via-area I.” Otherwise, if the “Via-area” is located on the GND layer 405, it is called a “Via-area II.”

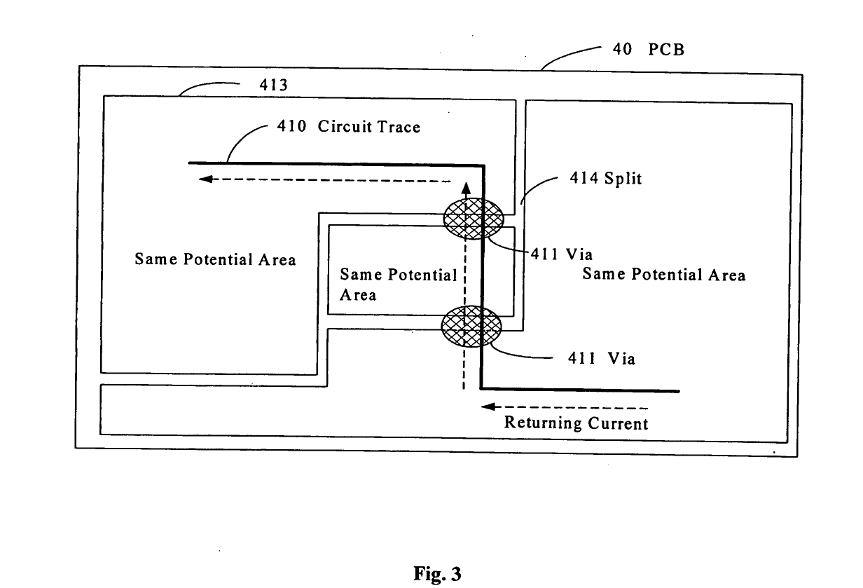

FIG. 3 is a schematic, planform view of part of the exemplary PCB 40, showing certain components including a trace 410 of the PCB 40. As described above, the traces 410 are mainly distributed on the signal layers 401, 403, 404 and 406, and the same potential areas 413 are mainly distributed on the Vcc layer 402 and the GND layer 405. Areas between two same potential areas 413 are called splits 414, which can block currents from passing between the same potential areas 413. When a current encounters a split 414, the current returns and flows to other areas, thus causing EMI. Therefore, the layout of traces 410 must be optimized by certain means, such as by using a via 411 or a capacitor 412 to conduct the current across the split 414.

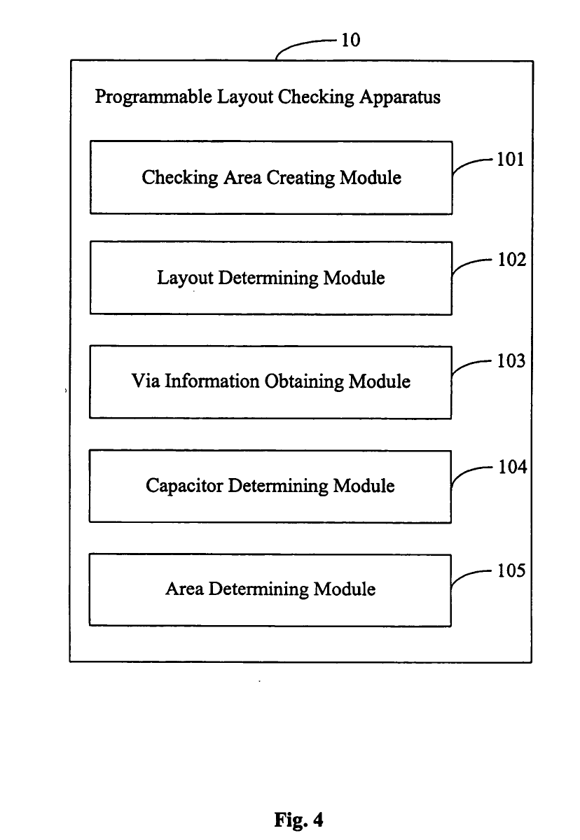

FIG. 4 is a schematic diagram of function modules of the programmable layout checking apparatus (hereinafter, “the checking apparatus”) 10. The checking apparatus 10 comprises a checking area creating module 101, a layout determining module 102, a via information obtaining module 103, a capacitor determining module 104, and an area determining module 105.

The checking area creating module 101 is for creating checking areas according to standard layout information stored in the standard layout information storage 21. The layout determining module 102 is for obtaining a reference layer of a signal layer on which a trace 410 to be checked is routed, and determining whether a vertical projection of the trace 410 intersects on any same potential area 413 on the reference layer. The via information obtaining module 103 is for obtaining actual via information from the actual layout information storage 22, obtaining reference layers of signal layers connected by a via, and determining whether any via 411 exists in a checking area. The capacitor determining module 104 is for determining whether any capacitor 412 exists in a checking area, and determining whether each capacitor 412 in the checking area has been listed in a user-selected capacitor list. The area determining module 105 is for obtaining information on same potential areas 413 from the actual layout information storage 22, and determining whether two selected same potential areas 413 have identical electrical characteristics according to the information on the two same potential areas 413.

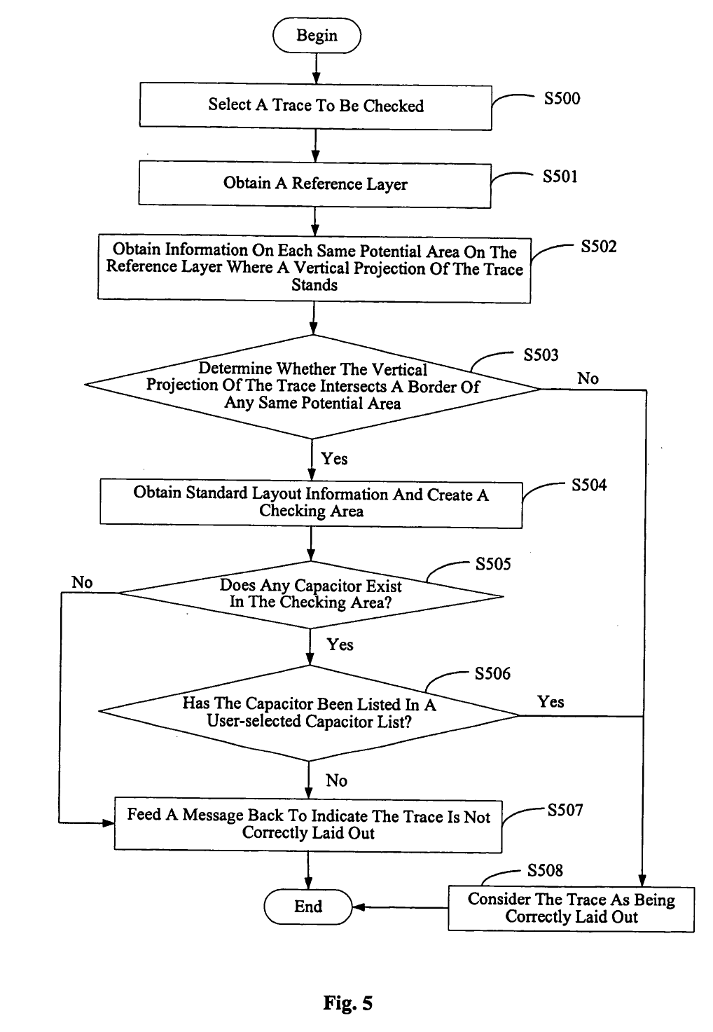

FIG. 5 is a flowchart of a preferred method for checking whether circuit traces 410, each of which is routed on a same signal layer of a PCB 40, have been correctly laid out. In this situation, the reference layer of the signal layer may be either a Vcc layer 402 or a GND layer 405, depending on a distance between the reference layer and the signal layer. If the distance between the Vcc layer 402 and the signal layer is shorter than the distance between the GND layer 405 and the signal layer, the Vcc layer 402 is selected as the reference layer. Otherwise, the GND layer 405 is selected as the reference layer.

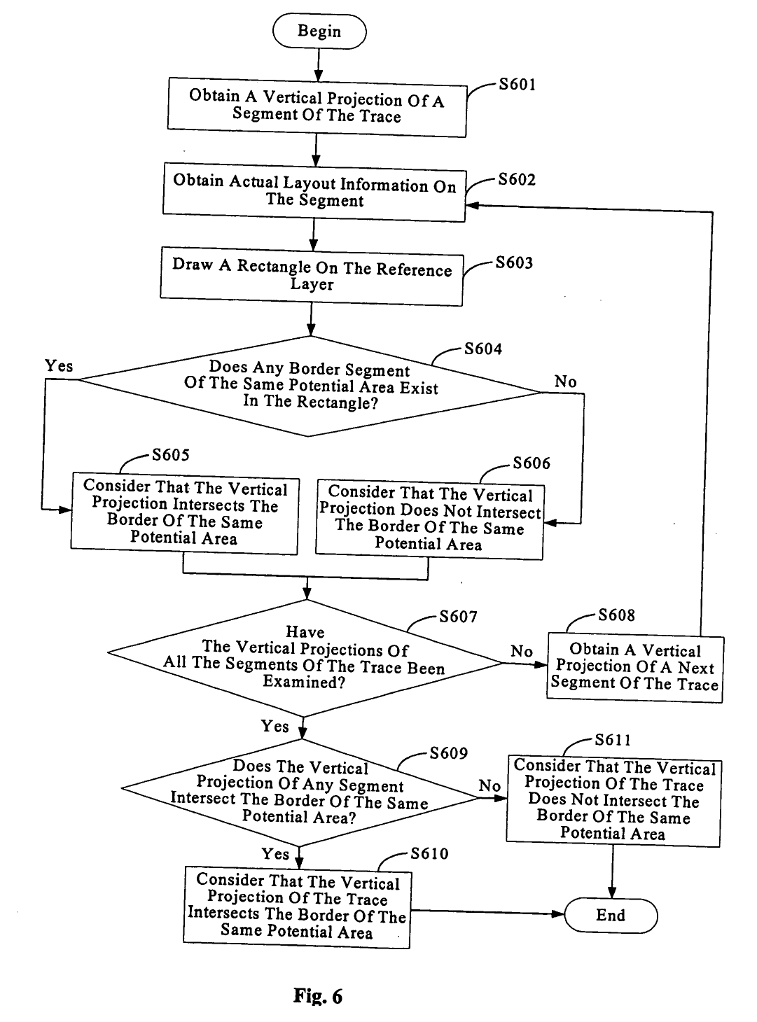

In step S500, a user selects a trace 410 to be checked through a user interface connected to the checking apparatus 10. In step S501, the layout determining module 102 obtains a reference layer of the signal layer on which the trace 410 is routed. In step S502, the area determining module 105 obtains from the actual layout information storage 22 information on each same potential area 413 on the reference layer where a vertical projection of the trace 410 stands. In step S503, the layout determining module 102 determines whether the vertical projection of the trace 410 on the reference layer intersects a border of any same potential area 413 identified in step S502 (this is described in detail below in relation to FIG. 6). If the vertical projection of the trace 410 on the reference layer intersects the border of any same potential area 413, the procedure goes to step S504 described below in respect of each such same potential area 413. If the vertical projection of the trace 410 on the reference layer does not intersect the border of any same potential area 413, the procedure goes directly to step S508 described below.

In step S504, the checking area creating module 101 obtains standard layout information on the PCB 40 from the standard layout information storage 21, and creates a checking area according to the standard layout information. In step S505, the capacitor determining module 104 determines whether any capacitor 412 exists in the checking area. If any capacitor 412 exists in the checking area, the procedure goes to step S506 described below. If no capacitor 412 exists in the checking area, the procedure goes directly to step S507 described below.

In step S506, the capacitor determining module 104 determines whether the capacitor 412 has been listed in the user-selected capacitor list, which is stored in a cache of the system (not shown). Note that the user-selected capacitor list stores information on capacitors 412 which designers choose to reduce EMI. Prior to checking a layout of traces 410 on a PCB 40, the information on capacitors 412 which designers choose to reduce EMI is copied from the standard layout information storage 21 into the user-selected capacitor list. If the capacitor 412 has not been listed in the user-selected capacitor list, the procedure goes to step S507 described below. If the capacitor 412 has been listed in the user-selected capacitor list, the procedure goes to step S508 described below.

In step S507, the checking apparatus 10 feeds a message back to the user, indicating that the trace 410 is not correctly laid out, whereupon the procedure is ended. In step S508, the trace 410 is considered as being correctly laid out, provided that no message has been fed back pursuant to step S507 in respect of any other same potential area. Thereupon the procedure is ended.

FIG. 6 is a flowchart of details of step S503 of FIG. 5, namely determining whether the vertical projection of the trace 410 on the reference layer intersects the border of any same potential area 413 identified in step S502. Commonly, a trace 410 is constituted by a plurality of segments. Therefore, step S503 can be performed by examining location relationships between the segments of the trace 410 and the same potential area 413; that is, by examining whether vertical projections of the segments of the trace 410 on the reference layer intersect the border of the same potential area 413. The procedure of FIG. 6 applies in respect of each same potential area 413 identified in step S502.

In step S601, the layout determining module 102 obtains a vertical projection of a segment of the trace 410. In step S602, the layout determining module 102 obtains actual layout information on the segment from the actual layout information storage 22. In step S603, the checking area creating module 101 draws a rectangle for examining on the reference layer, according to coordinate values of endpoints of the segment and a width of the segment. In step S604, the layout determining module 102 determines whether any border segment of the same potential area 413 exists in the rectangle. If any border segment exists in the rectangle, in step S605, the vertical projection of the segment is considered as intersecting the border of the same potential area 413, whereupon the procedure goes to step S607 described below. If no border segment exists in the rectangle, in step S606, the vertical projection of the segment is considered as not intersecting the border of the same potential area 413, whereupon the procedure goes to step S607 described below.

In step S607, the layout determining module 102 determines whether the vertical projections of all the segments of the trace 410 on the reference layer have been examined. If there are vertical projections of any segments of the trace 410 that have not been examined, in step S608, the layout determining module 102 obtains a vertical projection of a next segment of the trace 410, whereupon the procedure returns to step S602 described above. If the vertical projections of all the segments of the trace 410 have been examined, in step S609, the layout determining module 102 determines whether the vertical projection of the trace 410 intersects the border of the same potential area 413 according to the location relationships between the vertical projections of all the segments of the trace 410 and the same potential area 413. That is, if the vertical projection of any of the segments of the trace 410 intersects the border of the same potential area 413, in step S610, the vertical projection of the trace 410 is considered as intersecting the border of the same potential area 413. Otherwise, in step S611, the vertical projection of the trace 410 is considered as not intersecting the border of the same potential area 413.

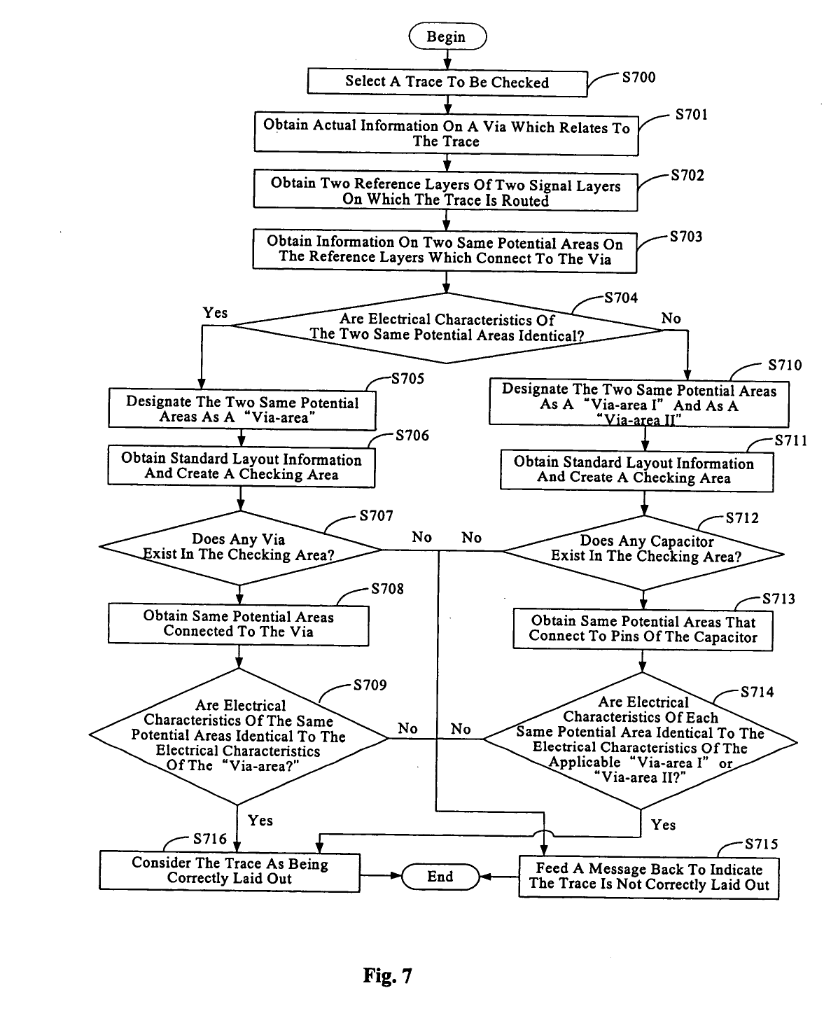

FIG. 7 is a flowchart of a preferred method for checking whether traces 410, each of which is routed on more than one signal layer of a PCB 40, have been correctly laid out. In this situation, segments of the trace 410 on two different signal layers are joined by one or more vias 411. The reference layers of the two signal layers can be the Vcc layer 402 and/or the GND layer 405, depending on distances between the reference layers and the two signal layers. For simplicity, only simple traces 410 are described below. That is, each simple trace 410 has all segments thereof routed on two signal layers only, with the segments on the two signal layers being joined by one via 411 only. Nevertheless, the present invention is not to be construed as to being limited to such simple traces 410. The method described below is adaptable for more complex traces 410. That is, in cases where each trace 410 has segments thereof routed on two or more different signal layers, with the segments on the signal layers being joined by more than one via 411.

In step S700, a user selects a trace 410 to be checked through a user interface connected to the checking apparatus 10. In step S701, the via information obtaining module 103 obtains actual information on a via 411 of the trace 410 from the actual layout information storage 22. In step S702, the via information obtain module 103 obtains two reference layers of the two signal layers on which the trace 410 is routed, and designates the two reference layers as a first layer and a second layer respectively. In step S703, the area determining module 105 obtains information on two same potential areas 413 respectively on the first layer and the second layer which connect to the via 411, from the actual layout information storage 22. In step S704, the area determining module 105 determines whether electrical characteristics of the two same potential areas 413 are identical. If the electrical characteristics of the two same potential areas 413 are identical, the procedure goes to step S705 described below. If the electrical characteristics of the two same potential areas 413 are not identical, the procedure goes directly to step S712 described below.

In step S705, the two same potential areas 413 are considered as one potential area designated as a “Via-area.” In step S706, the checking area creating module 101 obtains standard layout information on the PCB 40 from the standard layout information storage 21, and creates a checking area according to the standard layout information. In step S707, the via information obtaining module 103 determines whether any via 411 exists in the checking area. If no via 411 exists in the checking area, the procedure goes directly to step S710 described below. If any via 411 exists in the checking area, in step S708, the checking apparatus 10 obtains same potential areas 413 connected to the via 411. In step S709, the area determining module 105 determines whether electrical characteristics of the same potential areas 413 are identical to the electrical characteristics of the “Via-area.” If the electrical characteristics of the same potential areas 413 are not identical to the electrical characteristics of the “Via-area,” the procedure goes to step S715 described below. Otherwise, the procedure goes to step S716 described below.

In step S710, the two same potential areas 413 are respectively designated as a “Via-area I” and a “Via-area II.” In step S711, the checking area creating module 101 obtains standard layout information on the PCB 40 from the standard layout information storage 21, and creates a checking area according to the standard layout information. In step S712, the capacitor determining module 104 determines whether any capacitor 412 exists in the checking area. If no capacitor 412 exists in the checking area, the procedure goes directly to step S715 described below. If any capacitor 412 exists in the checking area, in step S713, with respect to each capacitor 412 identified in step S712, the checking apparatus 10 obtains two same potential areas 413 which connect to pins of the capacitor 412. In step S714, the area determining module 105 determines whether electrical characteristics of each same potential area 413 are identical to the electrical characteristics of either “Via-area I” or “Via-area II,” whichever of “Via-area I” and “Via-area II” is located on the same reference layer. If the electrical characteristics of either same potential area 413 are not identical to the electrical characteristics of the applicable “Via-area I” or “Via-area II,” in respect of all capacitors 412 identified in step S712, the procedure goes directly to step S715 described below. Otherwise, if the electrical characteristics of each same potential area 413 are identical to the electrical characteristics of the applicable “Via-area I” or “Via-area II,” in respect of any capacitor 412 identified in step S712, the procedure goes directly to step S716 described below.

In step S715, the checking apparatus 10 feeds a message back to the user indicating that the trace 410 is not correctly laid out, whereupon the procedure is ended. In step S716, the trace is considered as being correctly laid out, whereupon the procedure is ended.

Although the present invention has been specifically described on the basis of a preferred embodiment and preferred methods, the invention is not to be construed as being limited thereto. Various changes and modifications may be made to the embodiment and methods without departing from the scope and spirit of the invention.

1. A system for checking a layout of traces on a printed circuit board (PCB), the system comprising a computer and a database connected to the computer, wherein:
the database comprises:
a standard layout information storage for storing preset standard layout information on the PCB; and
an actual layout information storage for storing actual layout information on the PCB; and
the computer comprises:
a checking area creating module for creating checking areas according to the standard layout information;
a layout determining module for obtaining a reference layer of a signal layer on which a trace is routed, and determining whether a vertical projection of the trace intersects borders of any same potential areas on the reference layer;
a via information obtaining module for obtaining reference layers of signal layers connected by a via, and determining whether any via exists in a checking area;
a capacitor determining module for determining whether any capacitor exists in a checking area, and determining whether a capacitor in the checking area has been listed in a user-selected capacitor list; and
an area determining module for obtaining information on same potential areas of the PCB from the actual layout information storage, and determining whether the same potential areas have identical electrical characteristics according to the information on the same potential areas.

2. The system according to claim 1, further comprising a connection connecting the computer with the database.

3. The system according to claim 1, wherein the standard layout information comprises standard layout information on traces, and standard information on capacitors and vias.

4. The system according to claim 1, wherein the actual layout information comprises actual layout information on the traces, actual information on capacitors and vias, and information on the same potential areas.

5. The system according to claim 1, wherein the user-selected capacitor list is used for storing information on capacitors chosen to reduce electromagnetic interference (EMI).

6. The system according to claim 5, wherein said information on the capacitors is copied from the standard layout information storage.

7. A method for checking whether traces, each of which is routed on a same layer of a printed circuit board (PCB), have been correctly laid out, the method comprising the steps of:
(a) selecting a trace to be checked, wherein the trace is routed on only one signal layer of the PCB;
(b) obtaining a reference layer of the signal layer on which the trace is routed, and obtaining information on each same potential area on the reference layer where a vertical projection of the trace stands;
(c) determining whether the vertical projection of the trace on the reference layer intersects a border of any same potential area identified in step (b);
(d) obtaining standard layout information on the PCB, and creating a checking area according to the standard layout information on the PCB, if the vertical projection of the trace intersects the border of any same potential area identified in step (b), wherein this step and the following steps apply in respect of each same potential area identified in this step;
(e) determining whether any capacitor exists in the checking area;
(f) determining whether the capacitor has been listed in a user-selected capacitor list, if any capacitor exists in the checking area; and
(g) considering the trace as being correctly laid out with respect to the same potential area, if the capacitor has been listed in the user-selected capacitor list.

8. The method according to claim 7, wherein the standard layout information on the PCB comprises standard layout information on traces, and standard information on capacitors and vias.

9. The method according to claim 7, wherein step (c) comprises the following steps in respect of each same potential area identified in step (b):
obtaining a vertical projection of a segment of the trace on the reference layer;
drawing a rectangle on the reference layer according to coordinate values of endpoints of the segment and a width of the segment;
determining whether any border segment of the same potential area exists in the rectangle;
considering that the vertical projection of the segment does not intersect the border of the same potential area, if no border segment of the same potential area exists in the rectangle;
determining whether the vertical projections of all segments of the trace on the reference layer have been examined;
determining whether the vertical projection of the trace intersects the border of the same potential area according to location relationships between the vertical projections of all segments of the trace and the same potential area, if the vertical projections of all segments of the trace have been examined; and
considering that the vertical projection of the trace intersects the border of the same potential area, if the vertical projection of any segment of the trace intersects the border of the same potential area.

10. The method according to claim 9, further comprising the step of considering that the vertical projection of the segment intersects the border of the same potential area, if any border segment of the same potential area exists in the rectangle.

11. The method according to claim 9, further comprising the step of considering that the vertical projection of the trace does not intersect the border of the same potential area, if no vertical projection of any segment of the trace intersects the border of the same potential area.

12. The method according to claim 7, further comprising the step of considering that the trace is correctly laid out, if the vertical projection of the trace does not intersect the border of any same potential area identified in step (b).

13. The method according to claim 7, further comprising the step of considering the trace as being incorrectly laid out and feeding a message back to indicate that the trace is not correctly laid out, if the capacitor has not been listed in the user-selected capacitor list.

14. A method for checking whether traces, each of which is routed on more than one layer of a printed circuit board (PCB), have been correctly laid out, the method comprising the steps of:
(a) selecting a trace to be checked, wherein the trace has been routed on more than one of signal layers of the PCB;
(b) obtaining actual information on a via of the trace;
(c) obtaining two reference layers of two signal layers on which the trace is routed;
(d) obtaining information on two same potential areas which connect to the via on the two reference layers;
(e) determining whether electrical characteristics of the two same potential areas are identical;
(f) considering the two same potential areas as one potential area, and designating them as a “Via-area,” if the electrical characteristics of the two same potential areas are identical;
(g) obtaining standard layout information on the PCB, and creating a checking area according to the standard layout information;
(h) determining whether any via exists in the checking area;
(i) obtaining same potential areas connected to the via, if any via exists;
(j) determining whether electrical characteristics of the same potential areas are identical to the electrical characteristics of the “Via-area;” and
(k) considering that the trace is correctly laid out, if the electrical characteristics of the same potential areas are identical to the electrical characteristics of the “Via-area.”

15. The method according to claim 14, wherein the standard layout information on the PCB comprises standard layout information on traces, and standard information on capacitors and vias.

16. The method according to claim 14, further comprising the steps of:
designating the two same potential areas a “Via-area I” and a “Via-area II” respectively, if the electrical characteristics of the two same potential areas are not identical;
obtaining standard layout information on the PCB, and creating a checking area according to the standard layout information;
determining whether any capacitor exists in the checking area;
obtaining same potential areas which connect to pins of the capacitor, for each capacitor identified in the previous determining step, if any capacitor exists in the checking area;
determining whether electrical characteristics of each same potential area are identical to the electrical characteristics of either “Via-area I” or “Via-area II,” whichever of “Via-area I” and “Via-area II” is located on the same reference layer; and
considering that the trace is correctly laid out if, for any capacitor identified in said previous determining step, the electrical characteristics of each same potential area are identical to the electrical characteristics of the applicable “Via-area I” or “Via-area II.”

17. The method according to claim 16, further comprising the step of feeding a message back to indicate that the trace is not correctly laid out, if no capacitor exists in the checking area.

18. The method according to claim 16, further comprising the step of feeding a message back to indicate that the trace is not correctly laid out, if the electrical characteristics of either of the same potential areas are not identical to the electrical characteristics of the applicable “Via-area I” or “Via-area II,” for all capacitors identified in said previous obtaining step.

19. The method according to claim 14, further comprising the step of feeding a message back to indicate that the trace is not correctly laid out, if no via exists in the checking area according to step (h).

20. The method according to claim 14, further comprising the step of feeding a message back to indicate that the trace is not correctly laid out, if the electrical characteristics of the same potential areas are not identical to the electrical characteristics of the “Via-area” according to step (j).

21. A method for checking precision of trace layouts of a printed circuit board (PCB), comprising the steps of:
selecting a trace to be checked;
retrieving information of at least one reference layer having a same electrically potential level corresponding to said layout of said selected trace;
retrieving change information of locations of said at least one reference layer relative to said layout of said trace;
retrieving standard layout information of said layout of said trace on said PCB; and
identifying effectiveness of said layout of said trace based on comparison result of said change information of said layout of said trace and said standard layout information.

22. The method according to claim 21, further comprising the step of identifying existence of one of vias and capacitors along said layout of said trace before said effectiveness identifying step so as to facilitate comparison of said change information and said standard layout information.

23. The method according to claim 21, further comprising the step of identifying electrical characteristics of said at least one reference to acquire a number of said at least one reference needed to use before said effectiveness identifying step.
